(19) United States
(12) Patent Application Publication
(10) Pub. No.: US 2017/0098551 A1
(43) Pub. Date: Apr. 6, 2017

(54) BASE-ATTACHED ENCAPSULANT FOR SEMICONDUCTOR ENCAPSULATION, METHOD FOR MANUFACTURING BASE-ATTACHED ENCAPSULANT FOR SEMICONDUCTOR ENCAPSULATION, AND METHOD FOR MANUFACTURING SEMICONDUCTOR APPARATUS

(71) Applicant: SHIN-ETSU CHEMICAL CO., LTD., Tokyo (JP)

(72) Inventors: Tomoaki NAKAMURA, Annaka (JP); Hideki AKIBA, Annaka (JP); Toshio SHIOBARA, Annaka (JP); Shinsuke YAMAGUCHI, Annaka (JP)

(73) Assignee: SHIN-ETSU CHEMICAL CO., LTD., Tokyo (JP)

(21) Appl. No.: 15/251,047

(22) Filed: Aug. 30, 2016

(30) Foreign Application Priority Data
Oct. 6, 2015 (JP) 2015-198203

(51) Int. Cl. H01L 21/56; H01L 23/29; H01L 21/48; H01L 23/31

(52) U.S. Cl. CPC H01L 21/561; H01L 21/565; H01L 23/3135; H01L 23/29; H01L 21/481

(57) ABSTRACT

A base-attached encapsulant for semiconductor encapsulation, includes a base and encapsulating resin layer on one surface of the base, the base being composed of a fibrous base layer in which a thermosetting resin composition containing a thermosetting resin is impregnated into a fibrous base and cured, a cured material layer A composed of a cured material of the thermosetting resin composition formed on the fibrous base layer at the opposite side to the encapsulating resin layer, and a cured material layer B composed of a cured material of the thermosetting resin composition formed on the fibrous base layer at the encapsulating resin layer side. The thickness Ta of the cured material layer A is 0.5 μm or more. The ratio Ta/Tb of the thickness Ta of the cured material layer A and the thickness Tb of the cured material layer B is in a range of 0.1 to 10.

### BACKGROUND OF THE INVENTION

Field of the Invention

The present invention relates to an encapsulant capable of collectively encapsulating a device-mounted surface of a substrate on which semiconductor devices have been mounted, or a device-formed surface of a wafer on which semiconductor devices have been formed on a wafer level, particularly to a base-attached encapsulant for semiconductor encapsulation, a method for manufacturing the base-attached encapsulant for semiconductor encapsulation, and a method for manufacturing a semiconductor apparatus by using the base-attached encapsulant for semiconductor encapsulation.

Description of the Related Art

Various methods have heretofore been proposed and investigated about encapsulation, on a wafer level, of a device-mounted surface of a substrate on which semiconductor devices have been mounted or a device-formed surface of a wafer on which semiconductor devices have been formed, and there may be exemplified by a method of encapsulating by spin coating or screen printing (Patent Document 1), and a method of using a complex sheet where a heat fusible epoxy resin has been coated on a film support (Patent Document 2 and Patent Document 3).

Among these, as a method of encapsulating a device-mounted surface of a substrate on which semiconductor devices have been mounted on a water level, the following method has been mass-produced; a film having adhesive layers on both surfaces is bonded to an upper portion of a metal, a silicon wafer or a glass substrate, or an adhesive is applied to the same by spin coating, etc., then, the semiconductor devices are arranged on the substrate, adhered and mounted thereon to form a device-mounted surface, and the device-mounted surface is then encapsulated by pressure molding with a liquid epoxy resin or an epoxy molding compound, etc., under heating (Patent Document 4). Also, as a method of encapsulating the device-formed surface of a wafer on which semiconductor devices have been formed on a wafer level, a method of encapsulating the device-formed surface by pressure molding with a liquid epoxy resin or an epoxy molding compound, etc., under heating is recently being mass-produced.

The foregoing methods can encapsulate a small-diameter wafer with the diameter of 200 mm (8 inches) or so or a small-diameter substrate made of a metal, etc. without any big problems. When encapsulating a large-diameter substrate having semiconductor devices mounted thereon or a large-diameter wafer having semiconductor devices formed thereon with a diameter of 300 mm (12 inches) or more, however, there has been a big problem that the substrate or the wafer warps due to shrinkage stress of the encapsulating resin such as epoxy resin, at the time of encapsulating and curing. In addition, when the device-mounted surface of the large-diameter substrate on which semiconductor devices have been mounted is encapsulated on a wafer level, there arises a problem that the semiconductor devices are detached from the substrate made of a metal, etc. by shrinkage stress of the encapsulating resin at the time of encapsulating and curing. These problems have been large hindrance to mass-production of semiconductor apparatuses by collective encapsulation.

As a method for solving the above-mentioned problems, for collectively encapsulating a device-mounted surface of a substrate on which semiconductor devices have been mounted, there is a method of using a base-attached encapsulant for semiconductor encapsulation having a resin-impregnated fibrous base in which a thermosetting resin is impregnated into a fibrous base and the thermosetting resin is semi-cured or cured, and an encapsulating resin layer composed of an uncured thermosetting resin formed on one surface of the resin-impregnated fibrous base (Patent Document 5).

When such a base-attached encapsulant is used for semiconductor encapsulation, the resin-impregnated fibrous base having an extremely little expansion coefficient can suppress shrinkage stress of the encapsulating resin layer at the time of encapsulating and curing. Therefore, even when a large-diameter wafer or a large-diameter substrate made of a metal, etc. is encapsulated, a device-mounted surface of a substrate on which semiconductor devices have been mounted can be collectively encapsulated on a wafer level while suppressing warpage of the substrate or fall-off of the semiconductor devices from the substrate. Also, the base-attached encapsulant for semiconductor encapsulation has extremely high versatility and will be excellent in encapsulating properties such as heat resistance and humidity resistance after encapsulation.

A semiconductor apparatus encapsulated by using the above base-attached encapsulant for semiconductor encapsulation bears the surface of the base, and accordingly the appearance gets worse compared to a semiconductor apparatus encapsulated with a conventional thermosetting epoxy resin etc., and there arises a problem that the laser marking property is damaged.

As a method for solving such problems, Patent Document 6 has proposed a method of using a base-attached encapsulant for semiconductor encapsulation having a surface resin layer formed on the surface of the base. By using the base-attached encapsulant for semiconductor encapsulation having such a surface resin layer, it comes to be possible to manufacture a semiconductor apparatus having a good appearance and laser marking property.

However, by forming the surface resin layer onto the surface of the base, the base is liable to generate warpage due to the difference of the thermal expansion coefficient between the base and the surface resin layer, and accordingly it can be difficult to form an encapsulating resin layer onto the surface of the base. Moreover, there has been a problem of worsening the handling ability of the base-attached encapsulant for semiconductor encapsulation itself such as remaining of warpage of the base even after forming an encapsulating resin layer. Furthermore, there has been a problem that the producing cost increases due to an addition of a step for forming the surface resin layer.

### CITATION LIST

### Patent Literature

[Patent Document 1] Japanese Patent Laid-Open Publication No. 2002-179885

[Patent Document 2] Japanese Patent Laid-Open Publication No. 2009-060146

[Patent Document 3] Japanese Patent Laid-Open Publication No. 2007-001266

[Patent Document 4] Japanese Patent Laid-Open Publication No. 2004-504723

[Patent Document 5] Japanese Patent Laid-Open Publication No. 2012-151451

[Patent Document 6] Japanese Patent Laid-Open Publication No. 2015-026763

### SUMMARY OF THE INVENTION

The present invention has been accomplished to solve the above-described problems, and an object thereof is to provide a base-attached encapsulant for semiconductor encapsulation with low cost and excellent handling ability which can suppress warpage even when encapsulating a large-area substrate with thin thickness, has excellent encapsulating properties such as heat resistance and moisture resistance reliability, and can manufacture a semiconductor apparatus with good laser marking property; a method for manufacturing a semiconductor apparatus by using the same; and a method for manufacturing the base-attached encapsulant for semiconductor encapsulation.

To accomplish the above-mentioned object, the present invention provides a base-attached encapsulant for semiconductor encapsulation, comprising a base and an encapsulating resin layer containing an uncured or semi-cured thermosetting resin formed on one surface of the base,

the base being composed of

(a) a fibrous base layer in which a thermosetting resin composition containing a thermosetting resin is impregnated into a fibrous base and cured,

(b) a cured material layer A composed of a cured material of the thermosetting resin composition formed on the fibrous base layer at the opposite side to the encapsulating resin layer, and

(c) a cured material layer B composed of a cured material of the thermosetting resin composition formed on the fibrous base layer at the same side as the encapsulating resin layer, wherein

the thickness Ta of the cured material layer A is 0.5 μm or more, and the ratio Ta/Tb of the thickness Ta of the cured material layer A and the thickness Tb of the cured material layer B is in a range of 0.1 to 10.

When the thickness of the cured material layer A, which is the outer surface of the base in the base-attached encapsulant for semiconductor encapsulation, is 0.5 μm or more as described above, good laser marking property can be obtained. When the ratio Ta/Tb of the thickness Ta of the cured material layer A and the thickness Tb of the cured material layer B is in a range of 0.1 to 10, it is possible to suppress warpage of the base, and to make the base-attached encapsulant for semiconductor encapsulation have good handling ability. Accordingly, the inventive base-attached encapsulant for semiconductor encapsulation can be one with low cost and excellent handling ability which can suppress warpage even when encapsulating a large-area substrate with thin thickness, has excellent encapsulating properties such as heat resistance and moisture resistance reliability, and can manufacture a semiconductor apparatus having good laser marking property.

The ratio Ta/Tb of the thickness Ta of the cured material layer A and the thickness Tb of the cured material layer B is preferably in a range of 0.5 to 2.

When the ratio Ta/Tb is in such a range, it is possible to suppress warpage of the base further and to give better handling ability of the base-attached encapsulant for semiconductor encapsulation.

It is preferred that the thermosetting resin composition contain colorant.

When colorant is contained in the thermosetting resin composition composing a base, it is possible to achieve good appearance not only good laser marking property with low cost.

It is preferred that the thermosetting resin composition contain the colorant in an amount of 0.1 to 30 parts by mass based on 100 parts by mass of the thermosetting resin composition.

If the base-attached encapsulant contains such an amount of colorant, better appearance and laser marking property can be obtained.

The present invention also provides a method for manufacturing a semiconductor apparatus, comprising the steps of:

(1) coating a device-mounted surface of a substrate having semiconductor devices mounted thereon or a device-formed surface of a wafer having semiconductor devices formed thereon with the encapsulating resin layer of the foregoing base-attached encapsulant,

(2) collectively encapsulating the device-mounted surface or the device-formed surface by heating to cure the encapsulating resin layer, and

(3) dicing the encapsulated substrate having semiconductor devices mounted thereon or the encapsulated wafer having semiconductor devices formed thereon into each individual semiconductor apparatus.

Such a manufacturing method can manufacture a semiconductor apparatus with low cost, warpage is suppressed even when encapsulating a large-area substrate with thin thickness, and which can encapsulate semiconductor devices with an encapsulating resin layer having excellent encapsulating properties such as heat resistance and moisture resistance reliability, and has good appearance and laser marking property.

The present invention also provides a method for manufacturing a base-attached encapsulant for semiconductor encapsulation, comprising the steps of:

(i) producing bases by impregnating each fibrous base with a thermosetting resin composition containing a thermosetting resin, and heating to cure the thermosetting resin composition to produce each of the bases composed of a fibrous base layer in which the thermosetting resin composition is impregnated into the fibrous base and cured, a cured material layer A composed of a cured material of the thermosetting resin composition formed on one surface of the fibrous base layer, and a cured material layer B composed of a cured material of the thermosetting resin composition formed on the fibrous base layer at the opposite surface to the cured material layer A,

(ii) selecting a base in which the thickness Ta of the cured material layer A is 0.5 μm or more, and the ratio Ta/Tb of the thickness Ta of the cured material layer A and the thickness Tb of the cured material layer B is in a range of 0.1 to 10 from the produced bases, and

(iii) forming an encapsulating resin layer containing an uncured or semi-cured thermosetting resin on the selected base at the same side as the cured material layer B.

Such a manufacturing method can easily manufacture a base-attached encapsulant for semiconductor encapsulation, with low cost and excellent handling ability, which can suppress warpage even when encapsulating a large-area substrate with thin thickness, has excellent encapsulating properties such as heat resistance and moisture resistance reliability, and can manufacture a semiconductor apparatus with good laser marking property.

In the foregoing step (ii), it is preferable to select a base in which the thickness Ta of the cured material layer A is 0.5 μm or more, and the ratio Ta/Tb of the thickness Ta of the cured material layer A and the thickness Tb of the cured material layer B is in a range of 0.5 to 2.

By selecting and using a base with the ratio Ta/Tb in such a range, it is possible to suppress warpage of the base further and to give better handling ability of the base-attached encapsulant for semiconductor encapsulation.

It is preferred that the thermosetting resin composition contain colorant.

By using a thermosetting resin composition which contains colorant as described above, it is possible to achieve good appearance not only good laser marking property with low cost.

As the thermosetting resin composition, it is preferable to use one containing the foregoing colorant in an amount of 0.1 to 30 parts by mass based on 100 parts by mass of the thermosetting resin composition.

By using a thermosetting resin composition which contains such an amount of colorant, it is possible to achieve better appearance and laser marking property.

As described above, the inventive base-attached encapsulant for semiconductor encapsulation achieves low cost and excellent handling ability, can suppress warpage and fall-off of semiconductor devices from the substrate even when encapsulating a large-area substrate with thin thickness, has excellent encapsulating properties such as heat resistance and moisture resistance reliability, and can manufacture a semiconductor apparatus having good appearance and laser marking property. Moreover, the inventive manufacturing method can easily manufacture such a base-attached encapsulant for semiconductor encapsulation.

### BRIEF DESCRIPTION OF THE DRAWINGS

FIG. 1 is a schematic sectional view showing one example of the inventive base-attached encapsulant for semiconductor encapsulation;

FIG. 2 is a schematic sectional view showing one example of an encapsulated semiconductor device-mounted substrate obtained by collectively encapsulating a semiconductor device-mounted substrate by using the inventive base-attached encapsulant for semiconductor encapsulation;

FIG. 3 is a schematic sectional view showing one example of a semiconductor apparatus manufactured by using the inventive base-attached encapsulant for semiconductor encapsulation; and

FIG. 4 is a chart showing a temperature profile of the IR reflow apparatus (IR reflow condition) used for measurements of solder reflow resistance in the Examples.

### DETAILED DESCRIPTION OF THE PREFERRED EMBODIMENTS

As described above, it has been required to develop a base-attached encapsulant for semiconductor encapsulation which can suppress warpage even when encapsulating a large-area substrate with thin thickness, has excellent encapsulating properties such as heat resistance and moisture resistance reliability, and can manufacture a semiconductor apparatus with good laser marking property as well as achieving low cost and excellent handling ability.

The present inventors have diligently studied to solve the problems and have consequently found that the foregoing problems can be solved by setting the base of a base-attached encapsulant for semiconductor encapsulation to be a base having cured material layers formed on the both sides of a fibrous base layer in which a thermosetting resin composition containing a thermosetting resin is impregnated into a fibrous base and cured, and the thickness ratio of these cured material layers is in a specific range, thereby bringing the present invention to completion.

That is, the present invention is a base-attached encapsulant for semiconductor encapsulation, comprising a base and an encapsulating resin layer containing an uncured or semi-cured thermosetting resin formed on one surface of the base,

the base being composed of

(a) a fibrous base layer in which a thermosetting resin composition containing a thermosetting resin is impregnated into a fibrous base and cured,

(b) a cured material layer A composed of a cured material of the thermosetting resin composition formed on the fibrous base layer at the opposite side to the encapsulating resin layer, and

(c) a cured material layer B composed of a cured material of the thermosetting resin composition formed on the fibrous base layer at the same side as the encapsulating resin layer, wherein

the thickness Ta of the cured material layer A is 0.5 μm or more, and the ratio Ta/Tb of the thickness Ta of the cured material layer A and the thickness Tb of the cured material layer B is in a range of 0.1 to 10.

Hereinafter, a base-attached encapsulant for semiconductor encapsulation, a method for manufacturing the base-attached encapsulant for semiconductor encapsulation, and a method for manufacturing a semiconductor apparatus of the present invention will be specifically described, but the present invention is not limited thereto.

### [Base-Attached Encapsulant for Semiconductor Encapsulation]

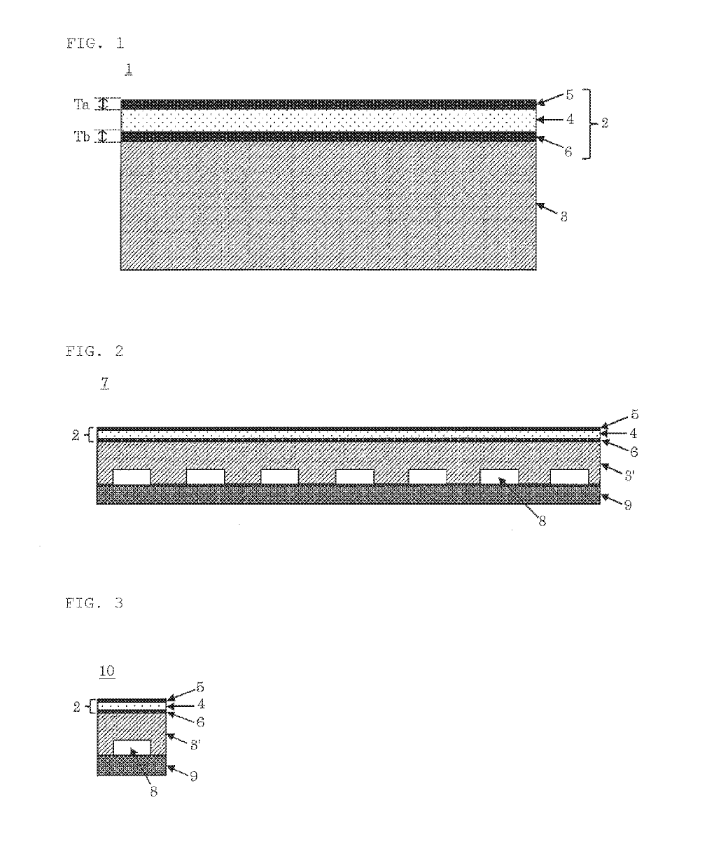

FIG. 1 is a schematic sectional view showing one example of the inventive base-attached encapsulant for semiconductor encapsulation. The base-attached encapsulant 1 for semiconductor encapsulation in FIG. 1 is composed of a base 2 and an encapsulating resin layer 3 formed on one surface of the base 2. The base 2 is composed of a fibrous base layer 4, a cured material layer A (5 in FIG. 1), and a cured material layer B (6 in FIG. 1). Hereinafter, each constituent components will be specifically described.

### <Base>

As shown in FIG. 1, the base 2 is composed of (a) a fibrous base layer 4, (b) a cured material layer A (5 in FIG. 1) formed on the fibrous base layer 4 at the opposite side to the encapsulating resin layer 3, and (c) a cured material layer B (6 in FIG. 1) formed on the fibrous base layer 4 at the same side as the encapsulating resin layer 3.

(a) Fibrous Base layer

The fibrous base layer comprises a thermosetting resin composition containing a thermosetting resin being impregnated into a fibrous base and cured.

### [Fibrous Base]

As the fibrous base which constitutes the fibrous base layer, any fiber can be used in accordance with product characteristics. Illustrative examples thereof include an inorganic fiber such as carbon fiber, glass fiber, quartz glass fiber, and metal fiber; an organic fiber such as aromatic polyamide fiber, polyimide fiber, and polyamideimide fiber; and further silicon carbide fiber, titanium carbide fiber, boron fiber, alumina fiber, etc. As a preferable fibrous base material, glass fiber, quartz glass fiber, and carbon fiber are particularly exemplified. Among them, glass fiber and quartz glass fiber, which have high insulation properties, are particularly preferable.

### [Thermosetting Resin Composition]

The thermosetting resin composition impregnated into the fibrous base contains a thermosetting resin.

### (Thermosetting Resin)

The thermosetting resin used for the thermosetting resin composition is not particularly limited. Illustrative examples thereof include an epoxy resin, a silicone resin, a hybrid resin composed of an epoxy resin and a silicone resin, and a cyanate ester resin, which are generally used for encapsulating the semiconductor devices. A thermosetting resin such as bismaleimide triazine (BT) resin can also be used.

### <<Epoxy Resin>>

The epoxy resin that can be used for the thermosetting resin composition in the present invention may be for example, but not particularly limited to, any known epoxy resins in a liquid state and a solid state at room temperature. Illustrative examples thereof include a bisphenol A type epoxy resin; a bisphenol F type epoxy resin; a biphenol type epoxy resin such as a 3,3′,5,5′-tetramethyl-4,4′-biphenol type epoxy resin, and a 4,4′-biphenol type epoxy resin; a phenol novolac type epoxy resin; a cresol novolac type epoxy resin; a bisphenol A novolac type epoxy resin; a naphthalenediol type epoxy resin; a trisphenylolmethane type epoxy resin; a tetrakisphenylolethane type epoxy resin; a phenoldicyclopentadiene novolac type epoxy resin; a hydrogenated epoxy resin thereof, the aromatic ring of which has been hydrogenated; and alicyclic epoxy resin. It is also possible to blend an epoxy resin other than the foregoing with a certain amount in accordance with a purpose and needs.

In the thermosetting resin composition containing an epoxy resin, a curing agent for the epoxy resin may be contained. Examples of a usable curing agent include a phenol novolac resin, various kinds of amine derivatives, an acid anhydride, and those in which an acid anhydride group is partially ring-opened to form a carboxylic acid. Above all, a phenol novolac resin is preferred to ensure the reliability of a semiconductor apparatus to be manufactured by using the inventive base-attached encapsulant for semiconductor encapsulation. It is particularly preferred that an epoxy resin and a phenol novolac resin be mixed such that the ratio of the epoxy group to the phenolic hydroxyl group is 1:0.8 to 1:1.3.

In addition, imidazole derivatives, phosphine derivatives, amine derivatives, a metal compound such as an organic aluminum compound may be used as a reaction promoter (a catalyst) to promote the reaction of the epoxy resin and the curing agent.

The thermosetting resin composition containing an epoxy resin may further contain various kinds of additives, if necessary. For example, for the purpose of improving the properties of the resin, various kinds of additives such as thermoplastic resins, thermoplastic elastomers, organic synthetic rubbers, stress lowering agents of silicone type or other type, waxes, and a halogen-trapping agent may be added depending on the purpose.

### <<Silicone Resin>>

As to the silicone resin which can be used for the thermosetting resin composition in the present invention, although it is not particularly limited, a thermosetting or UV curable silicone resin can be mentioned. In particular, the thermosetting resin composition containing a silicone resin preferably contains an addition curable silicone resin composition. The addition curable silicone resin composition particularly preferably includes (A) an organosilicon compound having a nonconjugated double bond (e.g., diorganopolysiloxane containing an alkenyl group), (B) an organohydrogenpolysiloxane, and (C) a platinum-based catalyst as essential components. These components of (A) to (C) will be described below.

Component (A): Organosilicon Compound having Nonconjugated Double Bond

Examples of the organosilicon compound having a nonconjugated double bond of the component (A) include an organopolysiloxane shown by the following general formula (1) such as a linear diorganopolysiloxane both molecular terminals of which are blocked with triorganosiloxy groups containing an aliphatic unsaturated bond:

R¹¹R¹²R¹³SiO—(R¹⁴R¹⁵SiO)ₐ—(R¹⁶R¹⁷—SiO)_{b}—SiR¹¹R¹²R¹³ (1)

wherein R¹¹ represents a monovalent hydrocarbon group containing a nonconjugated double bond, R¹² to R¹⁷ each represent an identical or different monovalent hydrocarbon group, and “a” and “b” are each an integer satisfying 0≦a≦500, 0≦b≦250, and 0≦a+b≦500.

In the general formula (1), R¹¹ is a monovalent hydrocarbon group containing a nonconjugated double bond, and preferably a monovalent hydrocarbon group containing a nonconjugated double bond of an aliphatic unsaturated bond as typified by an alkenyl group preferably having 2 to 8 carbon atoms, particularly preferably 2 to 6 carbon atoms.

In the general formula (1), R¹² to R¹⁷ are each the same or different monovalent hydrocarbon group; examples thereof include an alkyl group, an alkenyl group, an aryl group, and an aralkyl group each preferably having 1 to 20 carbon atoms, particularly preferably 1 to 10 carbon atoms. Among these, more preferable examples of R¹⁴ to R¹⁷ include a monovalent hydrocarbon group except for an aliphatic unsaturated bond; particularly preferable example thereof include an alkyl group, an aryl group, or aralkyl group, which do not have an aliphatic unsaturated bond such as an alkenyl group. Among these, R¹⁶ and R¹⁷ are preferably an aromatic monovalent hydrocarbon group, particularly preferably an aryl group having 6 to 12 carbon atoms, such as a phenyl group and a tolyl group.

In the general formula (1), “a” and “b” are each an integer satisfying 0≦a≦500, 0≦b≦250, and 0≦a+b≦500; “a” is preferably 10≦a≦500; “b” is preferably 0≦b≦150; and a+b preferably satisfies 10≦a+b≦500.

The organopolysiloxane represented by the general formula (1) can be obtained, for example, by an alkali equilibration reaction between a cyclic diorganopolysiloxane such as cyclic diphenylpolysiloxane or cyclic methylphenylpolysiloxane and a disiloxane such as diphenyltetravinyldisiloxane or divinyltetraphenyldisiloxane to constitute a terminal group. In this case, since, in an equilibration reaction by an alkali catalyst (particularly a strong alkali such as KOH), polymerization proceeds even with a small amount of the catalyst by an irreversible reaction; thereby a ring-opening polymerization alone proceeds quantitatively and a terminal blocking ratio becomes high. Therefore, a silanol group and a chlorine content are generally not contained.

The organopolysiloxane represented by the general formula (1) may be exemplified by the following,

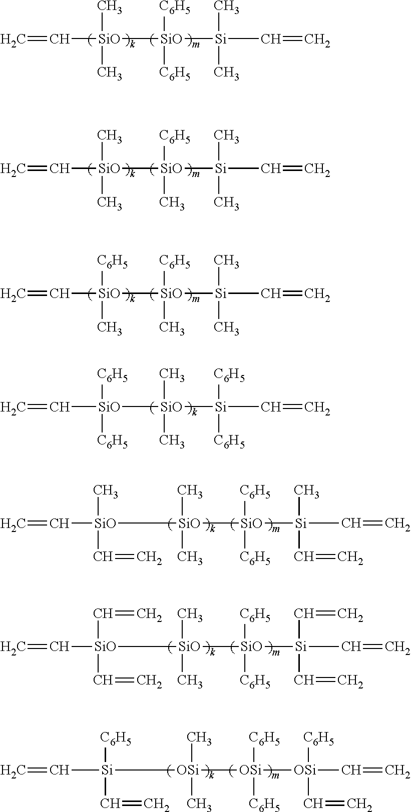

wherein “k” and “m” are each an integer satisfying 0≦k≦500, 0≦m≦250, and 0≦k+m≦500, preferably an integer satisfying 5≦k+m≦250 and 0≦m/(k+m)≦0.5.

The organopolysiloxane having a linear structure represented by the general formula (1) may be used as the component (A) in combination with an organopolysiloxane having a three-dimensional network structure including a trifunctional siloxane unit, a tetrafunctional siloxane unit, etc., if needed. Such an organosilicon compound having a nonconjugated double bond may be used alone or in combination of two or more kinds.

The amount of the group having a nonconjugated double bond (e.g., the monovalent hydrocarbon group having a double bond such as an alkenyl group and bonded to a Si atom) in the organosilicon compound having a nonconjugated double bond of the component (A), is preferably 0.1 to 20 mol % of the total amount of the monovalent hydrocarbon groups (the total amount of the monovalent hydrocarbon groups bonded to Si atoms), more preferably 0.2 to 10 mol %, particularly preferably 0.2 to 5 mol %. The reason why these amounts are preferable is that if the amount of the group having a nonconjugated double bond is 0.1 mol % or more, a good cured material can be obtained when it is cured, and if it is 20 mol % or less, the mechanical properties of a cured material become good.

In addition, the organosilicon compound having a nonconjugated double bond of the component (A) preferably contains an aromatic monovalent hydrocarbon group (an aromatic monovalent hydrocarbon group bonded to a Si atom); the content of the aromatic monovalent hydrocarbon group is preferably 0 to 95 mol % of the total amount of the monovalent hydrocarbon groups (the total amount of the monovalent hydrocarbon groups bonded to Si atoms), more preferably 10 to 90 mol %, particularly preferably 20 to 80 mol %. The aromatic monovalent hydrocarbon group provides a merit that a cured material has good mechanical properties and is easy to produce when it is contained in the resin with a suitable amount.

### Component (B): Organohydrogenpolysiloxane

The component (B) is preferably an organohydrogenpolysiloxane having two or more hydrogen atoms bonded to silicon atoms (hereinafter referred to as “SiH group”) per molecule. The organohydrogenpolysiloxane having two or more SiH groups in a molecule functions as a crosslinker and enables the formation of a cured material by addition reaction between the SiH group in the component (B) and the group having a nonconjugated double bond, such as a vinyl group or the other alkenyl group, in the component (A).

The organohydrogenpolysiloxane of the component (B) preferably has an aromatic monovalent hydrocarbon group. If the organohydrogenpolysiloxane has an aromatic monovalent hydrocarbon group, compatibility with the component (A) can be increased. Such an organohydrogenpolysiloxane may be used alone or in combination of two or more kinds. For example, the organohydrogenpolysiloxane having an aromatic hydrocarbon group may be contained as a part of the component (B) or used as all of the component (B).

Examples of the organohydrogenpolysiloxane of the component (B) include 1,1,3,3-tetramethyldisiloxane, 1,3,5,7-tetramethylcyclotetrasiloxane, tris(dimethyl-hydrogensiloxy)methylsilane, tris(dimethylhydrogensiloxy)-phenylsilane, 1-glycidoxypropyl-1,3,5,7-tetramethylcyclotetrasiloxane, 1,5-glycidoxypropyl-1,3,5,7-tetramethylcyclotetrasiloxane, 1-galycidoxypropyl-5-trimethoxysilylethyl-1,3,5,7-tetramethylcyclotetrasiloxane, methylhydrogenpolysiloxane both molecular terminals of which are blocked with trimethylsiloxy groups, a dimethyl-siloxane/methylhydrogensiloxane copolymer both molecular terminals of which are blocked with trimethylsiloxy groups, dimethylpolysiloxane both molecular terminals of which are blocked with dimethylhydrogensiloxy groups, a dimethyl-siloxane/methylhydrogensiloxane copolymer both molecular terminals of which are blocked with dimethylhydrogensiloxy groups, a methylhydrogensiloxane/diphenylsiloxane copolymer both molecular terminals of which are blocked with trimethylsiloxy groups, a methylhydrogensiloxane/diphenylsiloxane/dimethylsiloxane copolymer both molecular terminals of which are blocked with trimethylsiloxy groups, a trimethoxysilane polymer, a copolymer of (CH₃)₂HSiO_{1/2} units and SiO_{4/2} units, and a copolymer of (CH₃)₂HSiO_{1/2} units, SiO_{4/2} units, and (C₆H₅)SiO_{3/2} units, but it is not particularly limited.

In addition, compounds shown by the following structures or an organohydrogenpolysiloxane obtained by using these compounds as raw materials may also be used.

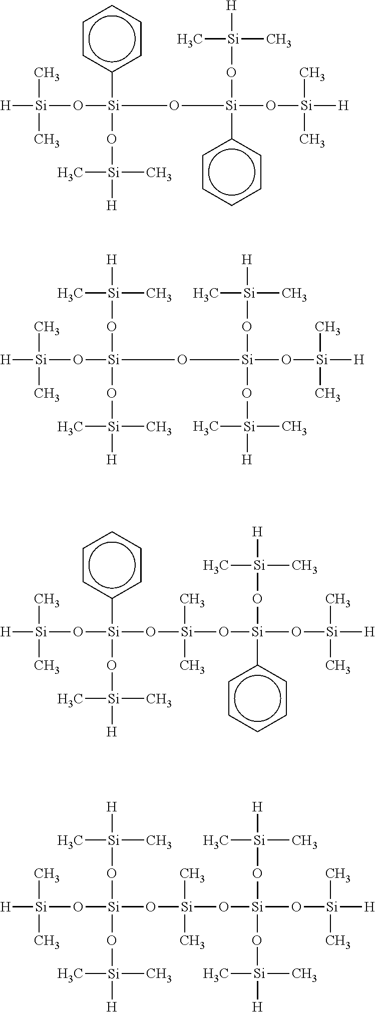

The molecular structure of the organohydrogen-polysiloxane of the component (B) may be any of a linear, cyclic, branched, or three-dimensional network structure, and the number of silicon atoms in one molecule (or a polymerization degree in case of a polymer) is preferably 2 or more, more preferably 3 to 500, particularly preferably 4 to 300 approximately.

The organohydrogenpolysiloxane of the component (B) is preferably contained such that the number of SiH group in the component (B) is 0.7 to 3.0, particularly 1.0 to 2.0 per one group having a nonconjugated double bond, such as an alkenyl group, in the component (A).

### Component (C): Platinum-Based Catalyst

Illustrative examples of the platinum-based catalyst of the component (C) include a chloroplatinic acid, an alcohol-modified chloroplatinic acid, a platinum complex having a chelate structure. These may be used alone or in combination of two or more kinds.

The amount of the platinum-based catalyst of the component (C) may be an effective amount for curing (a so-called catalytic amount). A preferable amount thereof is generally 0.1 to 500 ppm in terms of a mass of the platinum group metal per a total amount of 100 parts by mass of the component (A) and the component (B), and the range of 0.5 to 100 ppm is particularly preferable.

### <<Epoxy-Silicone Hybrid Resin>>

Examples of the epoxy resin and the silicone resin used in the hybrid resin which can be used for the thermosetting resin composition in the present invention, though they are not particularly limited, include the above-described epoxy resin and the above-described silicone resin.

### <<Cyanate Ester Resin>>

Examples of the cyanate ester resin which can be used for the thermosetting resin composition in the present invention, though it is not particularly limited, include a resin composition containing a cyanate ester compound or an oligomer thereof and a phenol compound and/or a dihydroxynaphthalene compound as a curing agent.

### Cyanate Ester Compound or Oligomer Thereof

The component used as a cyanate ester compound or an oligomer thereof is shown by the following general formula (2):

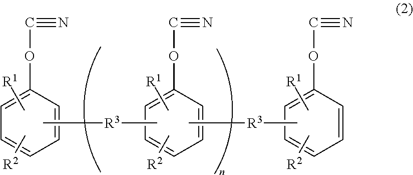

wherein R¹ and R² each represent a hydrogen atom or an alkyl group having 1 to 4 carbon atoms; R³ represents any of:

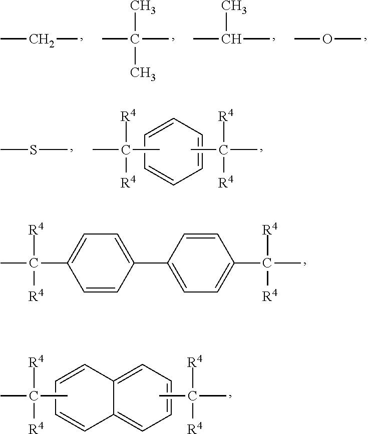

R⁴ represents a hydrogen atom or a methyl group; and “n” is an integer of 0 to 30.

The cyanate ester compound is a compound having two or more cyanate groups per molecule, and illustrative examples thereof include a cyanic acid ester of a polycyclic aromatic divalent phenol such as bis(3,5-dimethyl-4-cyanatephenyl)methane, bis(4-cyanatephenyl)methane, bis(3-methyl-4-cyanatephenyl)methane, bis(3-ethyl-4-cyanatephenyl)methane, bis(4-cyanatephenyl)-1,1-ethane, bis(4-cyanatephenyl)-2,2-propane, di(4-cyanatephenyl) ether, and di(4-cyanatephenyl)thio ether; a polycyanic acid ester of a polyvalent phenol such as a phenol novolac type cyanate ester, a cresol novolac type cyanate ester, a phenylaralkyl type cyanate ester, a biphenylaralkyl type cyanate ester, and a naphthalenearalkyl type cyanate ester.

The above-described cyanate ester compound can be obtained by reaction between phenols and cyanogen chloride under basic conditions. The cyanate ester compound may be selected properly depending on the use from the wide range of materials with characteristics varied due to its structure from a solid state having a softening point of 106° C. to a liquid state at room temperature.

Among them, a cyanate ester compound having a small cyanate group equivalent, i.e., a small amount of molecular weight between functional groups exhibits a slight curing shrinkage, enabling a cured product having low thermal expansion and high Tg (glass transition temperature) to be obtained. Meanwhile a cyanate ester compound having a large cyanate group equivalent exhibits a slightly reduced Tg but increases the flexibility of a triazine cross-linking distance, enabling reduction in elasticity, increase in toughness, and reduction in water absorbability to be expected.

Chlorine bonded to or remained in the cyanate ester compound is preferably 50 ppm or less, more preferably 20 ppm or less. If it is 50 ppm or less, there is few possibility that chlorine or chlorine ions, liberated by thermal decomposition when being stored at a high temperature for a long period of time, corrode an oxidized Cu frame, Cu wire or Ag plating, thereby causing exfoliation or electric failure; and the resin attains good insulation property.

### Curing Agent

Generally, as a curing agent and a curing catalyst of a cyanate ester resin, a metal salt, a metal complex, or a phenolic hydroxyl group or a primary amine each having an active hydrogen is used. In the present invention, a phenol compound or a dihydroxynaphthalene compound is preferably used.

Examples of the phenol compound which can be preferably used for the curing agent of the above-described cyanate ester resin, though it is not particularly limited, include ones shown by the following general formula (3):

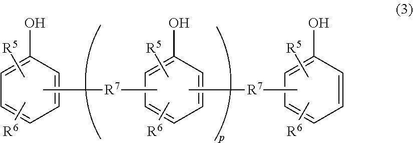

wherein R⁵ and R⁶ each represent a hydrogen atom or an alkyl group having 1 to 4 carbon atoms; R⁷ represents any of:

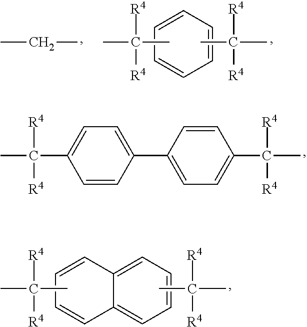

R⁴ represents a hydrogen atom or a methyl group; and “p” is an integer of 0 to 30.

Examples of the phenol compound include a phenol resin, a bisphenol F type resin, a bisphenol A type resin, a phenol novolac resin, a phenolaralkyl type resin, a biphenylaralkyl type resin, and a naphthalenearalkyl type resin having two phenolic hydroxyl groups per molecule; these may be used alone or in combination of two or more kinds.

Among the phenol compound, those having a small phenolic hydroxyl group equivalent, for example, a hydroxyl group equivalent of 120 or less, has high reactivity with a cyanate group, and therefore the curing reaction proceeds at a low temperature of 120° C. or lower. In this case, it is preferable to reduce the molar ratio of the hydroxyl group to the cyanate group. This ratio is preferably in the range of 0.05 to 0.11 mol per 1 mol of the cyanate group. In this case, a cured product which exhibits a slight curing shrinkage, a low thermal expansion, and high Tg can be obtained.

In contrast, a phenol compound having a large phenolic hydroxyl group equivalent, for example, a hydroxyl group equivalent of 175 or more, has an inhibited reactivity with a cyanate group, and therefore a composition having good storage stability and good flowability can be obtained. The ratio is preferably in the range of 0.1 to 0.4 mol per 1 mol of the cyanate group. In this case, a cured material having low water absorption but a slightly reduced Tg can be obtained. These phenol resins may be used in combination of two or more kinds to obtain desired curability and characteristics of the cured material.

The dihydroxynaphthalene which can be suitably used for the curing agent of the above-described cyanate ester resin is shown by the following general formula (4).

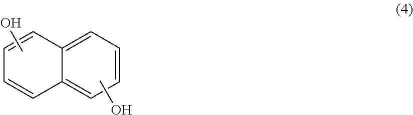

Examples of the dihydroxynaphthalene include 1,2-dihydroxynaphthalene, 1,3-dihydroxynaphthalene, 1,4-dihydroxynaphthalene, 1,5-dihydroxynaphthalene, 1,6-dihydroxynaphthalene, 1,7-dihydroxynaphthalene, 2,6-dihydroxynaphthalene, 2,7-dihydroxynaphthalene. 1,2-dihydroxynaphthalene, 1,3-dihydroxynaphthalene, and 1,6-dihydroxynaphthalene, each having a melting point of 130° C., have very high reactivity and promote cyclization reaction of the cyanate group with a small amount. 1,5-dihydroxynaphthalene and 2,6-dihydroxynaphthalene, each having a melting point of 200° C. or higher, relatively suppress the reaction.

Use of the dihydroxynaphthalene alone makes the molecular weight between functional groups small and the structure rigid, thereby enabling a cured produce having a slight curing shrinkage and high Tg to be obtained. In addition, use of the dihydroxynaphthalene in combination with a phenol compound that has two or more hydroxyl groups per molecule and hence has a large hydroxyl group equivalent enables the curability to be adjusted.

A halogen element and an alkali metal in the phenol compound and the dihydroxynaphthalene are preferably 10 ppm or less, particularly preferably 5 ppm or less when extracted at 120° C. under 2 atm.

### (Colorant)

In the present invention, the thermosetting resin composition preferably contains colorant in addition to the above-described thermosetting resin. When the thermosetting resin composition contains colorant, the cured material layer A, which is the outer surface of a base, contains colorant, and accordingly it is possible to suppress appearance failure and to improve the laser marking property.

The colorant to be used is not particularly limited, and any kind of known pigment and dye can be used alone or in combination of two or more kinds. Particularly, colorant with a color in the black range is preferable in view of improving the appearance and the laser marking property.

Illustrative examples of the colorant with a color in the black range include carbon black (furnace black, channel black, acetylene black, thermal black, lamp black, etc.), graphite, copper oxide, manganese dioxide, azo pigments (azomethine black, etc.), aniline black, perylene black, titanium black, cyanine black, active carbon, ferrite (non-magnetic ferrite, magnetic ferrite, etc.), magnetite, chromium oxide, iron oxide, molybdenum disulfide, a chromium complex, complex oxide black pigment (complex inorganic black pigment), anthraquinone type organic black pigment. Among them, carbon black is preferably used.

The colorant is preferably contained in an amount of 0.1 to 30 parts by mass, particularly 1 to 15 parts by mass based on 100 parts by mass of the thermosetting resin composition.

When the blending amount of the colorant is 0.1 parts by mass or more, good coloring of a base, suppressed appearance failure, and good laser marking property are realized. When the blending amount of the colorant is 30 parts by mass or less, it is possible to avoid markedly lowering of workability due to an increase of the viscosity of a thermosetting resin composition to be impregnated into a fibrous base in producing a base.

### (Inorganic Filler)

The thermosetting resin composition may be blended with an inorganic filler in the present invention. Examples of the inorganic filler to be blended include silica such as fused silica and crystalline silica, alumina, silicon nitride, aluminum nitride, aluminosilicate, boron nitride, glass fiber, and antimonous trioxide.

In particular, when the thermosetting resin composition contains an epoxy resin, the inorganic filler to be blended may be previously subjected to surface treatment with a coupling agent such as a silane coupling agent, a titanate coupling agent, etc. to increase bonding strength of the epoxy resin and the inorganic filler.

Preferable examples of the coupling agent include epoxy functional alkoxysilanes such as γ-glycidoxypropyltrimethoxysilane, γ-glycidoxypropylmethyldiethoxysilane, and β-(3,4-epoxycyclohexyl)ethyltrimethoxysilane; amino functional alkoxysilanes such as N-β-(aminoethyl)-γ-aminopropyltrimethoxysilane, γ-aminopropyltriethoxysilane, and N-phenyl-γ-aminopropyltrimethoxysilane; and mercapto functional alkoxysilanes such as γ-mercaptopropyltrimethoxysilane. Incidentally, the blending amount of the coupling agent to be used for the surface treatment and a method of the surface treatment are not particularly limited.

The blending amount of the inorganic filler is preferably 100 to 1,300 parts by mass, particularly preferably 200 to 1,000 parts by mass based on 100 parts by mass of the total mass of the resin component such as an epoxy resin and a silicone resin in the thermosetting resin composition. If it is 100 parts by mass or more, sufficient strength can be obtained. If it is 1,300 parts by mass or less, a failure in filling due to the reduction in flowability can be suppressed, whereby the semiconductor devices mounted on the substrate and the semiconductor devices formed on the wafer can be excellently encapsulated. This inorganic filler is preferably contained in an amount of 50 to 95% by mass, particularly 60 to 90% by mass based on the total mass of the thermosetting resin composition.

The fibrous base layer which constitutes the base of the inventive base-attached encapsulant for semiconductor encapsulation is the one in which the above-described thermosetting resin composition is impregnated into the above-described fibrous base and cured.

### (b) Cured Material Layer A and (c) Cured Material Layer B

As shown in FIG. 1, in the present invention, the base 2 is composed of the above-described fibrous base layer 4, a cured material layer A (5 in FIG. 1), and a cured material layer B (6 in FIG. 1). The cured material layer A (5 in FIG. 1) is a layer composed of a cured material of the above-described thermosetting resin composition and formed on the fibrous base layer 4 at the opposite side to the encapsulating resin layer 3. On the other hand, the cured material layer B (6 in FIG. 1) is a layer composed of a cured material of the above-described thermosetting resin composition and formed on the fibrous base layer 4 at the same side as the encapsulating resin layer 3 (i.e., at the opposite side to the cured material layer A).

In the present invention, the thickness Ta of the cured material layer A is 0.5 μm or more, preferably 5 to 30 μm. When the thickness Ta is less than 0.5 μm, the laser marking property gets markedly worse, whereas the present invention makes the thickness Ta 0.5 μm or more, and accordingly can ensure good laser marking property.

In the present invention, the ratio Ta/Tb of the thickness Ta of the cured material layer A and the thickness Tb of the cured material layer B is in a range of 0.1 to 10, preferably 0.5 to 2. When the ratio Ta/Tb is less than 0.1 or more than 10, there occurs warpage of the base, and accordingly the handling ability of the base-attached encapsulant for semiconductor encapsulation gets worse. On the other hand, in the present invention, since the Ta/Tb is 0.1 to 10, it is possible to suppress warpage of the base, and to realize good handling ability of the base-attached encapsulant for semiconductor encapsulation. When the Ta/Tb is in a range of 0.5 to 2, it is possible to further suppress warpage of the base, and to realize better handling ability of the base-attached encapsulant for semiconductor encapsulation.

It is to be noted that the thickness Tb of the cured material layer B is not particularly limited as long as it satisfies the foregoing ratio Ta/Tb, but it is preferably 0.5 μm or more, and more preferably in a range of 5 to 30 μm.

As described above, the base used for the inventive base-attached encapsulant for semiconductor encapsulation is the one composed of a fibrous base layer in which a thermosetting resin composition containing a thermosetting resin is impregnated into a fibrous base and cured, a cured material layer A of the thermosetting resin composition formed on the one side of the fibrous base layer, and a cured material layer B of the thermosetting resin composition formed on the other side of the fibrous base layer. The representative examples include a glass-epoxy substrate with cured material layers of an epoxy resin composition formed on the both sides thereof.

In the inventive base-attached encapsulant for semiconductor encapsulation, the thickness of the base (i.e., the total thickness of the fibrous base layer, the cured material layer A, and the cured material layer B) is preferably 20 μm to 1 mm, more preferably 30 μm to 500 μm. If it is 20 μm or more, it can suppress to easily deform due to thinness, while if it is 1 mm or less, it can also prevent an excessive increase in the thickness of the semiconductor apparatus itself so that the above range is preferred.

Such a base is important to reduce warpage of the semiconductor device-mounted substrate or the semiconductor device-formed wafer after collectively encapsulating their respective device-mounted surface or device-formed surface, and to reinforce the substrate or wafer on which one or more semiconductor devices have been arranged, bonded, or formed. Accordingly, the base is preferably hard and rigid material.

### <Encapsulating Resin Layer>

As shown in FIG. 1, the inventive base-attached encapsulant 1 for semiconductor encapsulation has an encapsulating resin layer 3 on the surface of the base 2 at the same side as the cured material layer B (6 in FIG. 1). This encapsulating resin layer 3 contains an uncured or semi-cured thermosetting resin. This encapsulating resin layer 3 has a role to collectively encapsulate a device-mounted surface of the substrate having semiconductor devices mounted thereon or a device-formed surface of the wafer having semiconductor devices formed thereon.

The thickness of the encapsulating resin layer is preferably 20 μm or more and 2,000 μm or less, although it is not particularly limited. The thickness of 20 μm or more is sufficient to encapsulate semiconductor device-mounted surfaces of various substrates having semiconductor devices mounted thereon, and can suppress a failure in filling due to thinness. The thickness of 2000 μm or less can prevent an excessive increase in the thickness of an encapsulated semiconductor apparatus, thereby being preferable.

The thermosetting resin used for the encapsulating resin layer is not particularly limited, but preferably is an thermosetting resin such as a liquid epoxy resin, a solid epoxy resin, a silicone resin, a hybrid resin of an epoxy resin and a silicone resin, or a cyanate ester resin each of which is generally used for encapsulating semiconductor devices. In particular, the thermosetting resin preferably contains any of an epoxy resin, a silicone resin, an epoxy-silicone hybrid resin, and a cyanate ester resin each of which solidifies at temperatures lower than 50° C. and melts at temperatures ranging from 50° C. to 150° C.

Illustrative examples of such an epoxy resin, a silicone resin, an epoxy-silicone hybrid resin, and a cyanate ester resin include the ones exemplified as a thermosetting resin contained in the above-described thermosetting resin composition to be impregnated into the foregoing fibrous base. It is also possible to blend an inorganic filler to the composition as in the above-described thermosetting resin composition to be impregnated into the fibrous base.

It is to be noted that the thermosetting resin used for the encapsulating resin layer and the thermosetting resin contained in the thermosetting resin composition to be impregnated into the fibrous base may be the same or different.

### [Method for Manufacturing the Base-Attached Encapsulant for Semiconductor Encapsulation]

The present invention also provides a method for manufacturing the above-mentioned base-attached encapsulant for semiconductor encapsulation. The inventive method for manufacturing the base-attached encapsulant for semiconductor encapsulation includes (i) a step of producing bases, (ii) a step of selecting a base, and (iii) a step of forming an encapsulating resin layer. Hereinafter, each steps will be described.

### (i) Step of Producing Bases

In the step of producing bases, a fibrous base is impregnated with a thermosetting resin composition containing a thermosetting resin, and the thermosetting resin composition is heated and cured to produce a base composed of a fibrous base layer in which the thermosetting resin composition is impregnated into the fibrous base and cured, a cured material layer A composed of a cured material of the thermosetting resin composition formed on one surface of the fibrous base layer, and a cured material layer B composed of a cured material of the thermosetting resin composition formed on the fibrous base layer at the opposite surface to the cured material layer A. As these fibrous base and thermosetting resin composition to be used, the above-described ones may be used. As this thermosetting resin composition, the one containing colorant is preferably used. By using a thermosetting resin composition containing colorant, it is possible to achieve good appearance not only good laser marking property with low cost. The colorant is preferably blended in an amount of 0.1 to 30 parts by mass based on 100 parts by mass of the thermosetting resin composition. By using a thermosetting resin composition containing such an amount of colorant, more favorable appearance and laser marking property can be obtained.

Illustrative examples of producing method of the base include a producing method of impregnating a fibrous base with a thermosetting resin composition by dipping the fibrous base into a thermosetting resin dispersion in which a thermosetting resin (and colorant or an inorganic filler if needed) is (are) dispersed into solvent (i.e., a thermosetting resin composition solution), and curing the thermosetting resin composition by heating in a heating oven or forming by a heating vacuum-press; a producing method of impregnating a fibrous base with a thermosetting resin composition and curing it by using a heating vacuum laminator, a heating vacuum-press, or a heating roll.

Regarding a method for adjusting the thicknesses of a cured material layer A and the cured material layer B constituting the base, when impregnated with a thermosetting resin dispersion using solvent, illustrative examples thereof include an adjusting method based on the viscosity of the dispersion, or a method in which a fibrous base impregnated with the thermosetting resin composition is passed through a roll with the gap adjusted. When forming a prepreg with a heating vacuum-press or impregnating a fibrous base with a thermosetting resin composition by using heated press, etc. without using solvent, illustrative examples thereof include a method of adjusting the melt viscosity of the thermosetting resin composition, and a method of adjusting the pressure of the press, etc.

### (ii) Step of Selecting Base

In the step of selecting a base, the bases produced by the foregoing methods are subjected to a selection to select a base in which the thickness Ta of the cured material layer A is 0.5 μm or more, and the ratio Ta/Tb of the thickness Ta of the cured material layer A and the thickness Tb of the cured material layer B is in a range of 0.1 to 10.

It is preferable to select the one in which the thickness Ta is 0.5 μm or more, and the ratio Ta/Tb is in a range of 0.5 to 2. By using the one having the Ta/Tb in such a range, it is possible to suppress warpage of the base further and to give better handling ability of the base-attached encapsulant for semiconductor encapsulation.

(iii) Step of Forming Encapsulating Resin Layer

In the step of forming an encapsulating resin layer, an encapsulating resin layer containing an uncured or semi-cured thermosetting resin is formed on the base selected as described above at the same side as the cured material layer B. As this thermosetting resin, the foregoing ones can be used.

The encapsulating resin layer can be formed by various methods such as a method in which a composition containing an uncured or semi-cured thermosetting resin in a sheet-form or a film-form is laminated onto the selected base at the same side as the cured material layer B to form the encapsulating resin layer by using vacuum laminator, a high-temperature vacuum-press, or a heating roll; a method in which a composition containing a thermosetting resin such as a liquid epoxy resin and a silicone resin is applied by printing, dispensing, or the like under reduced pressure or vacuum and heated; or a method in which a composition containing an uncured or semi-cured thermosetting resin is press formed.

By the foregoing inventive producing method, the inventive base-attached encapsulant for semiconductor encapsulation can be produced easily with low cost. Such an inventive base-attached encapsulant for semiconductor encapsulation has excellent handling ability and can suppress shrinkage stress of the encapsulating resin layer in curing and encapsulating, and accordingly can suppress warpage and fall-off of semiconductor devices from the substrate even when encapsulating a large-area substrate with thin thickness. Moreover, when the thickness of the cured material layer A, which is the outer surface of the base, is 0.5 μm or more, good laser marking property can be obtained. Furthermore, when colorant is contained in the thermosetting resin composition, the cured material layer A of the thermosetting resin composition containing colorant is exposed as the outer surface of the base, and accordingly it is possible to achieve good appearance not only good laser marking property.

### [Method for Manufacturing Semiconductor Apparatus]

The present invention also provides a method for manufacturing a semiconductor apparatus by using the foregoing inventive base-attached encapsulant for semiconductor encapsulation. The inventive method for manufacturing a semiconductor apparatus includes (1) a step of coating, (2) a step of encapsulating, and (3) a step of dicing. Hereinafter, each steps will be described.

### (1) Step of Coating

First, in the step of coating, a device-mounted surface of a substrate having semiconductor devices mounted thereon or a device-formed surface of a wafer having semiconductor devices formed thereon is coated with the foregoing encapsulating resin layer of the inventive base-attached encapsulant for semiconductor encapsulation.

### <Semiconductor Device-Mounted Substrate and Semiconductor Device-Formed Wafer>

The semiconductor device-mounted substrate targeted by encapsulating with the inventive base-attached encapsulant for semiconductor encapsulation is not particularly limited. Illustrative examples thereof include an organic substrate, an inorganic substrate such as a silicon wafer, and a metal substrate having semiconductor devices mounted on the device-mounted surface. This semiconductor device-mounted substrate includes semiconductor-devices-array on which semiconductor devices are mounted and arranged.

The semiconductor device-formed wafer is a wafer having semiconductor devices formed thereon. Herein, usable wafer includes a silicon (Si) wafer, an SiC wafer, etc.

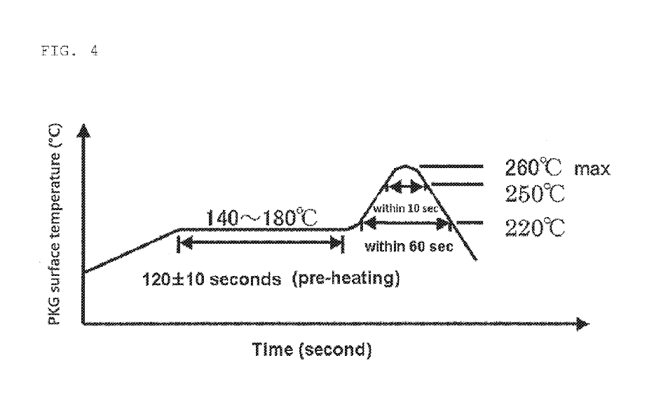

Hereinafter, as an example of the method for manufacturing a semiconductor apparatus, a case of encapsulating a device-mounted surface of a substrate having semiconductor devices mounted thereon will be described with reference to FIG. 2 and FIG. 3. In a wafer having semiconductor devices formed thereon, however, it is also possible to encapsulate semiconductor devices and to manufacture a semiconductor apparatus by the same way.

### (2) Step of Encapsulating

Then, in the step of encapsulating, the encapsulating resin layer is heated to cure, thereby collectively encapsulating a device-mounted surface or a device-formed surface. This gives an encapsulated semiconductor device-mounted substrate 7 in which the device-mounted surface of a semiconductor device-mounted substrate 9 having a semiconductor device 8 mounted thereon is encapsulated with a cured encapsulating resin layer 3′ as shown in FIG. 2.

### (3) Step of Dicing

Then, in the step of dicing, the encapsulated semiconductor device-mounted substrate or semiconductor device-formed wafer is subjected to dicing to manufacture each individual semiconductor apparatus. This gives a semiconductor apparatus 10 which is obtained by dicing the encapsulated semiconductor device-mounted substrate 7 into each individual pieces as shown in FIG. 3.

Such a method for manufacturing a semiconductor apparatus can suppress the shrinkage stress of the encapsulating resin layer in curing and encapsulating by using the above-described base-attached encapsulant, and accordingly can suppress warpage in encapsulating a large-area substrate with thin thickness while suppressing warpage of the base and fall-off of the semiconductor devices from the substrate in manufacturing a semiconductor apparatus. Moreover, when the thickness of the cured material layer A, which becomes the outer surface of the base, is 0.5 μm or more, good laser marking property can be obtained. Furthermore, when colorant is contained in the thermosetting resin composition, the cured material layer A of the thermosetting resin composition containing colorant is exposed as the outer surface of the base, and accordingly it is possible to achieve good appearance not only good laser marking property.

As described above, the inventive base-attached encapsulant for semiconductor encapsulation achieves low cost and excellent handling ability, can suppress warpage and fall-off of semiconductor devices from the substrate even when encapsulating a large-area substrate with thin thickness, has excellent encapsulating properties such as heat resistance and moisture resistance reliability, and can manufacture a semiconductor apparatus having good appearance and laser marking property. Moreover, the inventive manufacturing method can easily manufacture such a base-attached encapsulant for semiconductor encapsulation.

### EXAMPLES

Hereinafter, the present invention will be described in more detail with reference to Examples and Comparative Examples, but the present invention is not restricted to thereto.

### Example 1

### Preparation of Resin Composition for Producing Base

Into 60 parts by mass of a cresol novolac type epoxy resin, 30 parts by mass of a phenol novolac resin, and 0.6 part by mass of a catalyst TPP (triphenylphosphine), 300 parts by mass of toluene was added. This was stirred and mixed to prepare a toluene dispersion of an epoxy resin composition.

### <Production of Base>

To this toluene dispersion of an epoxy resin composition, E-glass cloth (manufactured by Nitto Boseki co., Ltd., thickness: 50 μm) as a fibrous base was dipped to impregnate the E-glass cloth with the toluene dispersion of the epoxy resin composition. The glass cloth was passed through a roll with the gap adjusted to 75 μm, and then left for 15 minutes at 120° C. to volatilize toluene. The glass cloth was subjected to heat molding at 175° C. for 5 minutes to obtain a molded article. This was subjected to heating at 180° C. for 4 hours (post cure) to cure the impregnated thermosetting resin composition, thereby obtaining an epoxy resin-impregnated fibrous base X1 in which cured material layers of the epoxy resin composition were formed on the both sides of the fibrous base layer. In the obtained epoxy resin-impregnated fibrous base X1, the thicknesses of the cured material layers A and B of the epoxy resin composition formed on the both sides of the fibrous base layer were measured by a cross-section observation to find that the thickness Ta of the cured material layer A was 10 μm and the thickness Tb of the cured material layer B was 12 μm, which confirmed that this base can be used for the present invention. It is to be noted that the handling ability was favorable.

### <Preparation of Resin Composition for Encapsulating Resin Layer>

By using a high-speed mixing apparatus, 60 parts by mass of a cresol novolac type epoxy resin, 30 parts by mass of a phenol novolac resin, 400 parts by mass of spherical silica having an average particle diameter of 7 m, 0.2 part by mass of a catalyst TPP, and 0.5 part by mass of a silane coupling agent (KBM403: available from Shin-Etsu Chemical Co., Ltd.) were sufficiently mixed, and then kneaded under heating with a continuous kneading apparatus to form a sheet and was cooled. The sheet was crushed to obtain an epoxy resin composition as granular powder.

### <Manufacture of Base-Attached Encapsulant for Semiconductor Encapsulation>

Onto the above-described epoxy resin-impregnated fibrous base X1, the above-mentioned granular powder of the epoxy resin composition was uniformly dispersed. The temperatures of the upper and lower mold were set at 80° C., a PET film (peeling film) coated with a fluorine resin was set to the upper mold, and the pressure at the inside of the mold was reduced to a vacuum level and compression molding was carried out for 3 minutes so that a thickness of the resin became 600 μm to form an encapsulating resin layer. As described above, a base-attached encapsulant Y1 for semiconductor encapsulation was manufactured.

### (Preparation of Semiconductor Device-Mounted Substrate)

A substrate in which 64 Si chips each having a thickness of 200 μm and a size of 10×10 mm had been mounted on a BT substrate having a thickness of 100 μm and a size of 74×240 mm was prepared.

### (Encapsulation of Semiconductor Device-Mounted Substrate)

By using the base-attached encapsulant Y1 for semiconductor encapsulation manufactured in the foregoing, the above-described semiconductor device-mounted substrate was encapsulated and then cured by vacuum compression molding for 5 minutes using a vacuum lamination apparatus (manufactured by Nichigo-Morton Co., Ltd.), a plate temperature of which being set to 175° C. After curing and encapsulating, the resultant substrate was post-cured at 180° C. for 4 hours to obtain an encapsulated semiconductor device-mounted substrate.

### Example 2

### Preparation of Resin Composition for Producing Base

Into 60 parts by mass of a cresol novolac type epoxy resin, 30 parts by mass of a phenol novolac resin, 3 parts by mass of titanium black as a black pigment, and 0.6 part by mass of a catalyst TPP, 300 parts by mass of toluene was added. This was stirred and mixed to prepare a toluene dispersion of an epoxy resin composition.

### <Production of Base>

To this toluene dispersion of an epoxy resin composition, E-glass cloth (manufactured by Nitto Boseki co., Ltd., thickness: 50 m) as a fibrous base was dipped to impregnate the E-glass cloth with the toluene dispersion of the epoxy resin composition. The glass cloth was passed through a roll with the gap adjusted to 75 μm, and then left for 15 minutes at 120° C. to volatilize toluene. The glass cloth was subjected to heat molding at 175° C. for 5 minutes to obtain a molded article. This was subjected to heating at 180° C. for 4 hours (post cure) to cure the impregnated thermosetting resin composition, thereby obtaining an epoxy resin-impregnated fibrous base X2 in which cured material layers of the epoxy resin composition were formed on the both sides of the fibrous base layer. In the obtained epoxy resin-impregnated fibrous base X2, the thicknesses of the cured material layers A and B of the epoxy resin composition formed on the both sides of the fibrous base layer were measured by a cross-section observation to find that the thickness Ta of the cured material layer A was 8 μm and the thickness Tb of the cured material layer B was 14 μm, which confirmed that this base can be used for the present invention. It is to be noted that the handling ability was favorable.

### <Preparation of Resin Composition for Encapsulating Resin Layer>

In the same manner as in Example 1, granular powder of an epoxy resin composition was obtained.

### <Manufacture of Base-Attached Encapsulant for Semiconductor Encapsulation>

A base-attached encapsulant Y2 for semiconductor encapsulation was manufactured in the same manner as in Example 1 except for using the epoxy resin-impregnated fibrous base X2 obtained above in place of the epoxy resin-impregnated fibrous base X1.

### <Preparation of Semiconductor Device-Mounted Substrate>

A semiconductor device-mounted substrate was prepared in the same manner as in Example 1.

### <Encapsulation of Semiconductor Device-Mounted Substrate>

An encapsulated semiconductor device-mounted substrate was obtained in the same manner as in Example 1 except for using the base-attached encapsulant Y2 for semiconductor encapsulation manufactured above in place of the base-attached encapsulant Y1 for semiconductor encapsulation.

### Example 3

### Preparation of Resin Composition for Producing Base

Into 50 parts by mass of dimethylpolysiloxane both molecular terminals of which were blocked with vinyl groups as an organosilicon compound having a nonconjugated unsaturated bond, 50 parts by mass of dimethylpolysiloxane both molecular terminals of which were blocked with dimethylhydrogensiloxy groups, 0.2 part by mass of acetylene alcohol-based ethynylcyclohexanol as a reaction inhibitor, 0.1 part by mass of an octyl alcohol-modified solution of a chloroplatinic acid, and 3 parts by mass of carbon black as a black pigment, 200 parts by mass of toluene was added. This was stirred and mixed to prepare a toluene dispersion of a silicone resin composition.

### <Production of Base>

To this toluene dispersion of a silicone resin composition, E-glass cloth (manufactured by Nitto Boseki co., Ltd., thickness: 50 μm) as a fibrous base was dipped to impregnate the E-glass cloth with the toluene dispersion of the silicone resin composition. The glass cloth was passed through a roll with the gap adjusted to 90 μm, and then left for 15 minutes at 120° C. to volatilize toluene. The glass cloth was subjected to heat molding at 175° C. for 5 minutes to obtain a molded article. This was subjected to heating at 150° C. for 10 minutes (post cure) to cure the impregnated thermosetting resin composition, thereby obtaining a silicone resin-impregnated fibrous base X3 in which cured material layers of the silicone resin composition were formed on the both sides of the fibrous base layer. In the obtained silicone resin-impregnated fibrous base X3, the thicknesses of the cured material layers A and B of the silicone resin composition formed on the both sides of the fibrous base layer were measured by a cross-section observation to find that the thickness Ta of the cured material layer A was 15 μm and the thickness Tb of the cured material layer B was 22 μm, which confirmed that this base can be used for the present invention. It is to be noted that the handling ability was favorable.

### <Preparation of Resin Composition for Encapsulating Resin Layer>

To a composition containing 50 parts by mass of dimethylpolysiloxane both molecular terminals of which were blocked with vinyl groups, 50 parts by mass of dimethylpolysiloxane both molecular terminals of which were blocked with dimethylhydrogensiloxy groups, 0.2 part by mass of acetylene alcohol-based ethynylcyclohexanol as a reaction inhibitor, and 0.1 part by mass of an octyl alcohol-modified solution of a chloroplatinic acid described above was added 350 parts by mass of spherical silica having an average particle diameter of 5 μm, and the mixture was well stirred with a planetary mixer heated at 60° C. and then formed to a sheet-form to prepare a sheet of the silicone resin composition.

### <Manufacture of Base-Attached Encapsulant for Semiconductor Encapsulation>

Onto the above-described silicone resin-impregnated fibrous base X3, the above-mentioned sheet of the silicone resin composition was laminated. The temperatures of the upper and lower mold were set at 80° C., a PET film (peeling film) coated with a fluorine resin was set to the upper mold, and the pressure at the inside of the mold was reduced to a vacuum level and compression molding was carried out for 3 minutes so that a thickness of the resin became 600 μm to form an encapsulating resin layer. As described above, a base-attached encapsulant Y3 for semiconductor encapsulation was manufactured.

### <Preparation of Semiconductor Device-Mounted Substrate>

A semiconductor device-mounted substrate was prepared in the same manner as in Example 1.

### <Encapsulation of Semiconductor Device-Mounted Substrate>

An encapsulated semiconductor device-mounted substrate was obtained in the same manner as in Example 1 except for using the base-attached encapsulant Y3 for semiconductor encapsulation manufactured above in place of the base-attached encapsulant Y1 for semiconductor encapsulation.

### Example 4

### Production of Base

A silicone resin-impregnated fibrous base X4 in which cured material layers of the silicone resin composition were formed on the both sides of the fibrous base layer was obtained in the same manner as in Example 3 except for passing the E-glass cloth through a roll with the gap adjusted to 70 μm after dipping the glass cloth into the toluene dispersion of the silicone resin composition. In the obtained silicone resin-impregnated fibrous base X4, the thicknesses of the cured material layers A and B of the silicone resin composition formed on the both sides of the fibrous base layer were measured by a cross-section observation to find that the thickness Ta of the cured material layer A was 12 urn and the thickness Tb of the cured material layer B was 6 μm, which confirmed that this base can be used for the present invention. It is to be noted that the handling ability was favorable.

### <Preparation of Resin Composition for Encapsulating Resin Layer>

In the same manner as in Example 3, a sheet of the silicone resin composition was obtained.

### <Manufacture of Base-Attached Encapsulant for Semiconductor Encapsulation>

A base-attached encapsulant Y4 for semiconductor encapsulation was manufactured in the same manner as in Example 3 except for using the silicone resin-impregnated fibrous base X4 obtained above in place of the silicone resin-impregnated fibrous base X3.

### <Preparation of Semiconductor Device-Mounted Substrate>

A semiconductor device-mounted substrate was prepared in the same manner as in Example 3.

### <Encapsulation of Semiconductor Device-Mounted Substrate>

An encapsulated semiconductor device-mounted substrate was obtained in the same manner as in Example 3 except for using the base-attached encapsulant Y4 for semiconductor encapsulation manufactured above in place of the base-attached encapsulant Y3 for semiconductor encapsulation.

### Example 5

### Preparation of Resin Composition for Producing Base

By using a high-speed mixing apparatus, 60 parts by mass of a cresol novolac type epoxy resin, 30 parts by mass of a phenol novolac resin, 350 parts by mass of spherical silica having an average particle diameter of 3 m, 0.2 part by mass of a catalyst TPP, 0.5 part by mass of a silane coupling agent (KBM403: available from Shin-Etsu Chemical Co., Ltd.), and 3 parts by mass of carbon black as a black pigment were sufficiently mixed, and then kneaded under heating with a continuous kneading apparatus to form a sheet and was cooled. The sheet was crushed to obtain an epoxy resin composition as granular powder.

### <Production of Base>

Onto an E-glass cloth (manufactured by Nitto Boseki co., Ltd., thickness: 50 μm) used as a fibrous base, the foregoing granular powder of the epoxy resin composition was placed on the surface of the glass cloth to which a cured material layer A would be formed. The epoxy resin composition was impregnated into the glass cloth and cured by vacuum-compression molding at 1 MPa for 5 minutes with a vacuum-press machine set to 175° C., thereby obtaining an epoxy resin-impregnated fibrous base X5 in which cured material layers of the epoxy resin composition were formed on the both sides of the fibrous base layer. In the obtained epoxy resin-impregnated fibrous base X5, the thicknesses of the cured material layers A and B of the epoxy resin composition formed on the both sides of the fibrous base layer were measured by a cross-section observation to find that the thickness Ta of the cured material layer A was 50 μm and the thickness Tb of the cured material layer B was 5 μm, which confirmed that this base can be used for the present invention. It is to be noted that the handling ability was favorable.

### <Preparation of Resin Composition for Encapsulating Resin Layer>

In the same manner as in Example 1, granular powder of an epoxy resin composition was obtained.

### <Manufacture of Base-Attached Encapsulant for Semiconductor Encapsulation>

A base-attached encapsulant Y5 for semiconductor encapsulation was manufactured in the same manner as in Example 1 except for using the epoxy resin-impregnated fibrous base X5 obtained above in place of the epoxy resin-impregnated fibrous base X1.

### <Preparation of Semiconductor Device-Mounted Substrate>

A semiconductor device-mounted substrate was prepared in the same manner as in Example 1.

### <Encapsulation of Semiconductor Device-Mounted Substrate>

An encapsulated semiconductor device-mounted substrate was obtained in the same manner as in Example 1 except for using the base-attached encapsulant Y5 for semiconductor encapsulation manufactured above in place of the base-attached encapsulant Y1 for semiconductor encapsulation.

### Example 6

### Preparation of Resin Composition for Producing Base

By using a high-speed mixing apparatus, 60 parts by mass of a cresol novolac type epoxy resin, 30 parts by mass of a phenol novolac resin, 30 parts by mass of spherical silica having an average particle diameter of 3 μm, 0.2 part by mass of a catalyst TPP, 0.5 part by mass of a silane coupling agent (KBM403: available from Shin-Etsu Chemical Co., Ltd.), and 3 parts by mass of carbon black as a black pigment were sufficiently mixed, and then kneaded under heating with a continuous kneading apparatus to form a sheet and was cooled to obtain a sheet-formed epoxy resin composition.

### <Production of Base>

Onto an E-glass cloth (manufactured by Nitto Boseki co., Ltd., thickness: 50 μm) used as a fibrous base, the foregoing sheet-formed epoxy resin composition was spread on the surface of the glass cloth to which a cured material layer A would be formed. Then, the epoxy resin composition was impregnated into the glass cloth and cured by vacuum-compression molding at 5 MPa for 5 minutes with a vacuum-press machine with the plate temperature being set to 175° C., thereby obtaining an epoxy resin-impregnated fibrous base X6 in which cured material layers of the epoxy resin composition were formed on the both sides of the fibrous base layer. In the obtained epoxy resin-impregnated fibrous base X6, the thicknesses of the cured material layers A and B of the epoxy resin composition formed on the both sides of the fibrous base layer were measured by a cross-section observation to find that the thickness Ta of the cured material layer A was 3 μm and the thickness Tb of the cured material layer B was 30 μm, which confirmed that this base can be used for the present invention. It is to be noted that the handling ability was favorable.

### <Preparation of Resin Composition for Encapsulating Resin Layer>

In the same manner as in Example 1, granular powder of an epoxy resin composition was obtained.

### <Manufacture of Base-Attached Encapsulant for Semiconductor Encapsulation>

A base-attached encapsulant Y6 for semiconductor encapsulation was manufactured in the same manner as in Example 1 except for using the epoxy resin-impregnated fibrous base X6 obtained above in place of the epoxy resin-impregnated fibrous base X1.

### <Preparation of Semiconductor Device-Mounted Substrate>

A semiconductor device-mounted substrate was prepared in the same manner as in Example 1.

### <Encapsulation of Semiconductor Device-Mounted Substrate>

An encapsulated semiconductor device-mounted substrate was obtained in the same manner as in Example 1 except for using the base-attached encapsulant Y6 for semiconductor encapsulation manufactured above in place of the base-attached encapsulant Y1 for semiconductor encapsulation.

### [Comparative Example 1] (Comparative Example when Encapsulated with Encapsulating Resin Layer Only)

### Preparation of Resin Composition for Encapsulating Resin Layer

In the same manner as in Example 1, granular powder of an epoxy resin composition was obtained.

### <Preparation of Semiconductor Device-Mounted Substrate>

A semiconductor device-mounted substrate was prepared in the same manner as in Example 1.

### <Encapsulation of Semiconductor Device-Mounted Substrate>

The foregoing granular powder of an epoxy resin composition was uniformly spread onto the semiconductor device-mounted substrate and then cured to encapsulate it by vacuum compression molding for 5 minutes using a vacuum lamination apparatus (manufactured by Nichigo-Morton Co., Ltd.), a plate temperature of which being set to 175° C. After curing and encapsulating, the resultant substrate was post-cured at 180° C. for 4 hours to obtain an encapsulated semiconductor device-mounted substrate.

### [Comparative Example 2] (Comparative Example in which Ta<0.5 μm)

### Production of Base

An epoxy resin-impregnated fibrous base X7 in which cured material layers of an epoxy resin composition were formed on the both sides of the fibrous base layer was obtained in the same manner as in Example 1 except for passing the E-glass cloth through a roll with the gap adjusted to 50 μm after dipping the glass cloth into the toluene dispersion of the epoxy resin composition. In the obtained epoxy resin-impregnated fibrous base X7, the thicknesses of the cured material layers A and B of the epoxy resin composition formed on the both sides of the fibrous base layer were measured by a cross-section observation to find that the thickness Ta of the cured material layer A was 0.4 μm and the thickness Tb of the cured material layer B was 0.3 μm. Its handling ability was favorable.

### <Preparation of Resin Composition for Encapsulating Resin Layer>

In the same manner as in Example 1, granular powder of an epoxy resin composition was obtained.

### <Manufacture of Base-Attached Encapsulant for Semiconductor Encapsulation>

A base-attached encapsulant Y7 for semiconductor encapsulation was manufactured in the same manner as in Example 1 except for using the epoxy resin-impregnated fibrous base X7 obtained above in place of the epoxy resin-impregnated fibrous base X1.

### <Preparation of Semiconductor Device-Mounted Substrate>

A semiconductor device-mounted substrate was prepared in the same manner as in Example 1.

### <Encapsulation of Semiconductor Device-Mounted Substrate>

An encapsulated semiconductor device-mounted substrate was obtained in the same manner as in Example 1 except for using the base-attached encapsulant Y7 for semiconductor encapsulation manufactured above in place of the base-attached encapsulant Y1 for semiconductor encapsulation.

### [Comparative Example 3] (Comparative Example in which Ta/Tb<0.1)

### Production of Base

An epoxy resin-impregnated fibrous base X8 in which cured material layers of an epoxy resin composition were formed on the both sides of the fibrous base layer was obtained in the same manner as in Example 1 except the E-glass cloth was not passed through a roll after being impregnated with the toluene dispersion of the epoxy resin composition. In the obtained epoxy resin-impregnated fibrous base X8, the thicknesses of the cured material layers A and B of the epoxy resin composition formed on the both sides of the fibrous base layer were measured by a cross-section observation to find that the thickness Ta of the cured material layer A was 10 μm and the thickness Tb of the cured material layer B was 120 μm (Ta/Tb≈0.08). This epoxy resin-impregnated fibrous base X8 got largely warped to be difficult to form an encapsulating resin layer, and showed very bad handling ability.

### <Preparation of Resin Composition for Encapsulating Resin Layer>

In the same manner as in Example 1, granular powder of an epoxy resin composition was obtained.

### <Manufacture of Base-Attached Encapsulant for Semiconductor Encapsulation>

A base-attached encapsulant Y8 for semiconductor encapsulation was manufactured in the same manner as in Example 1 except for using the epoxy resin-impregnated fibrous base X8 obtained above in place of the epoxy resin-impregnated fibrous base X1.

### <Preparation of Semiconductor Device-Mounted Substrate>

A semiconductor device-mounted substrate was prepared in the same manner as in Example 1.

### <Encapsulation of Semiconductor Device-Mounted Substrate>

An encapsulated semiconductor device-mounted substrate was obtained in the same manner as in Example 1 except for using the base-attached encapsulant Y8 for semiconductor encapsulation manufactured above in place of the base-attached encapsulant Y1 for semiconductor encapsulation.

### [Comparative Example 4] (Comparative Example in which Ta/Tb>10)

### Production of Base

An epoxy resin-impregnated fibrous base X9 in which cured material layers of an epoxy resin composition were formed on the both sides of the fibrous base layer was obtained in the same manner as in Example 5 except for using a resin composition for producing a base in which the blending amount of the spherical silica having an average particle diameter of 3 μm was modified to 600 parts by mass. In the obtained epoxy resin-impregnated fibrous base X9, the thicknesses of the cured material layers A and B of the epoxy resin composition formed on the both sides of the fibrous base layer were measured by a cross-section observation to find that the thickness Ta of the cured material layer A was 50 μm and the thickness Tb of the cured material layer B was 4 μm (Ta/Tb=12.5). This epoxy resin-impregnated fibrous base X9 got largely warped to be difficult to form an encapsulating resin layer, and showed very bad handling ability.

### <Preparation of Resin Composition for Encapsulating Resin Layer>

In the same manner as in Example 5, granular powder of an epoxy resin composition was obtained.

### <Manufacture of Base-Attached Encapsulant for Semiconductor Encapsulation>

A base-attached encapsulant Y9 for semiconductor encapsulation was manufactured in the same manner as in Example 5 except for using the epoxy resin-impregnated fibrous base X9 obtained above in place of the epoxy resin-impregnated fibrous base X5.

### <Preparation of Semiconductor Device-Mounted Substrate>

A semiconductor device-mounted substrate was prepared in the same manner as in Example 5.

### <Encapsulation of Semiconductor Device-Mounted Substrate>

An encapsulated semiconductor device-mounted substrate was obtained in the same manner as in Example 5 except for using the base-attached encapsulant Y9 for semiconductor encapsulation manufactured above in place of the base-attached encapsulant Y5 for semiconductor encapsulation.

Characteristics of the encapsulated semiconductor device-mounted substrates obtained in Examples 1 to 6 and Comparative Examples 1 to 4, i.e. the semiconductor apparatuses before dicing, were evaluated as described below. The evaluation results are shown in Table 1.

### [Warpage]

By using a laser three-dimensional measurement machine, displacement of the height of the encapsulated semiconductor device-mounted substrate was measured in the diagonal direction, and the difference in the displacement was made an amount of warpage (mm).

### [Appearance]

The surface of the encapsulated semiconductor device-mounted substrate was visually observed to be evaluated as “pass” when the surface unevenness and roughness were within a latitude, or “good” when these were scarcely observed.

### [Laser Marking Property]

The cured material layer A of the base in the encapsulated semiconductor device-mounted substrate was marked with a masking type YAG laser marking machine (under the conditions of applied voltage: 2.4 kV, pulse width: 120 μs) manufactured by NEC Corporation, and visibility of the printing (marking property) was evaluated.

### [Solder Reflow Resistance]

The encapsulated semiconductor device-mounted substrates obtained in Examples and Comparative Examples were each diced into individual pieces to manufacture semiconductor apparatuses, and left in a thermo-hygrostat at 85° C. and 60% RH for 168 hours to absorb moisture. Then, IR reflow condition shown in FIG. 4 was applied 3 times by using an IR reflow apparatus to conduct an TR reflow process (based on JEDEC Level 2 at 260° C.). The occurrence of an internal crack and fall-off were observed by an ultrasonic testing apparatus and observation of the cross-section of a cut semiconductor device. The number of packages containing a crack or fall-off was counted among a total of 20 packages.

TABLE 1

| | | | | | | | Comparative | Comparative | Comparative | Comparative |
|---|---|---|---|---|---|---|---|---|---|---|
| | Example 1 | Example 2 | Example 3 | Example 4 | Example 5 | Example 6 | Example 1 | Example 2 | Example 3 | Example 4 |
| Ta (μm) | 10 | 8 | 15 | 12 | 50 | 3 | — | 0.4 | 10 | 50 |
| Tb (μm) | 12 | 14 | 22 | 6 | 5 | 30 | — | 0.3 | 120 | 4 |
| Ta/Tb | 0.83 | 0.57 | 0.68 | 2 | 10 | 0.1 | — | 1.3 | 0.08 | 12.5 |
| Handling | good | good | good | good | good | good | — | good | bad | bad |
| ability of | | | | | | | | | | |
| base | | | | | | | | | | |
| Warpage of | <0.1 | <0.1 | <0.1 | <0.1 | <0.1 | <0.1 | 18 | <0.1 | <0.1 | <0.1 |
| package (mm) | | | | | | | | | | |
| Appearance | pass | good | good | good | good | good | pass | pass | pass | pass |
| of package | | | | | | | | | | |
| Laser marking | good | good | good | good | good | good | good | bad | good | good |
| property | | | | | | | | | | |
| Number of packages | 0/20 | 0/20 | 0/20 | 0/20 | 0/20 | 0/20 | 5/20 | 0/20 | 0/20 | 0/20 |
| cotaining | | | | | | | | | | |
| crack or fall- | | | | | | | | | | |
| off after IR | | | | | | | | | | |
| reflow process | | | | | | | | | | |

As shown in Table 1, in Examples 1 to 6 using the inventive base-attached encapsulant for semiconductor encapsulation, warpages of the encapsulated semiconductor device-mounted substrates were remarkably suppressed, the substrates showed excellent handling ability and good laser marking property, and the individual diced semiconductor apparatuses scarcely generated cracks or fall-off after IR reflow process. In Example 1, in which the resin composition for producing a base did not contain colorant, the appearance of package was within a latitude. Moreover, in Examples 2 to 5, in which each resin composition for producing a base contained colorant, the packages showed better appearances.

On the other hand, in Comparative Example 1, in which the encapsulation was performed with an encapsulating resin and without base, warpage of the encapsulated semiconductor device-mounted substrate was not suppressed, and the individual diced semiconductor apparatuses generated many cracks or fall-off after IR reflow process. In Comparative Example 2, in which the thickness of the cured material layer A formed on the fibrous base layer was less than 0.5 μm, markedly bad laser marking property was revealed. Comparative Example 3, in which the ratio Ta/Tb of the thicknesses of the cured material layer A and the cured material layer B formed on the fibrous base layer was less than 0.1, and Comparative Example 4, in which Ta/Tb is more than 10, the base itself warped and showed markedly bad handling ability such as difficulty to form an encapsulating resin layer.

As described above, it has revealed that the inventive base-attached encapsulant for semiconductor encapsulation can be a base-attached encapsulant with low cost and good handling ability, can collectively encapsulate the device-mounted surface or the device-formed surface while suppressing warpage of a substrate and fall-off of semiconductor devices from the substrate in manufacturing a semiconductor apparatus, and additionally, can manufacture a semiconductor apparatus with good laser marking property, and can improve the appearance of its package by blending colorant to the resin composition for producing a base.

It is to be noted that the present invention is not restricted to the foregoing embodiment. The embodiment is just an exemplification, and any examples that have substantially the same feature and demonstrate the same functions and effects as those in the technical concept described in claims of the present invention are included in the technical scope of the present invention.

What is claimed is:

1. A base-attached encapsulant for semiconductor encapsulation, comprising a base and an encapsulating resin layer containing an uncured or semi-cured thermosetting resin formed on one surface of the base,
the base being composed of
(a) a fibrous base layer in which a thermosetting resin composition containing a thermosetting resin is impregnated into a fibrous base and cured,
(b) a cured material layer A composed of a cured material of the thermosetting resin composition formed on the fibrous base layer at the opposite side to the encapsulating resin layer, and
(c) a cured material layer B composed of a cured material of the thermosetting resin composition formed on the fibrous base layer at the same side as the encapsulating resin layer, wherein
the thickness Ta of the cured material layer A is 0.5 μm or more, and the ratio Ta/Tb of the thickness Ta of the cured material layer A and the thickness Tb of the cured material layer B is in a range of 0.1 to 10.

2. The base-attached encapsulant according to claim 1, wherein the ratio Ta/Tb of the thickness Ta of the cured material layer A and the thickness Tb of the cured material layer B is in a range of 0.5 to 2.

3. The base-attached encapsulant according to claim 1, wherein the thermosetting resin composition contains colorant.

4. The base-attached encapsulant according to claim 2, wherein the thermosetting resin composition contains colorant.

5. The base-attached encapsulant according to claim 3, wherein the thermosetting resin composition contains the colorant in an amount of 0.1 to 30 parts by mass based on 100 parts by mass of the thermosetting resin composition.

6. The base-attached encapsulant according to claim 4, wherein the thermosetting resin composition contains the colorant in an amount of 0.1 to 30 parts by mass based on 100 parts by mass of the thermosetting resin composition.

7. A method for manufacturing a semiconductor apparatus, comprising the steps of:
(1) coating a device-mounted surface of a substrate having semiconductor devices mounted thereon or a device-formed surface of a wafer having semiconductor devices formed thereon with the encapsulating resin layer of the base-attached encapsulant according to claim 1,
(2) collectively encapsulating the device-mounted surface or the device-formed surface by heating to cure the encapsulating resin layer, and
(3) dicing the encapsulated substrate having semiconductor devices mounted thereon or the encapsulated wafer having semiconductor devices formed thereon into each individual semiconductor apparatus.

8. A method for manufacturing a semiconductor apparatus, comprising the steps of:
(1) coating a device-mounted surface of a substrate having semiconductor devices mounted thereon or a device-formed surface of a wafer having semiconductor devices formed thereon with the encapsulating resin layer of the base-attached encapsulant according to claim 2,
(2) collectively encapsulating the device-mounted surface or the device-formed surface by heating to cure the encapsulating resin layer, and
(3) dicing the encapsulated substrate having semiconductor devices mounted thereon or the encapsulated wafer having semiconductor devices formed thereon into each individual semiconductor apparatus.

9. A method for manufacturing a semiconductor apparatus, comprising the steps of:
(1) coating a device-mounted surface of a substrate having semiconductor devices mounted thereon or a device-formed surface of a wafer having semiconductor devices formed thereon with the encapsulating resin layer of the base-attached encapsulant according to claim 3,
(2) collectively encapsulating the device-mounted surface or the device-formed surface by heating to cure the encapsulating resin layer, and
(3) dicing the encapsulated substrate having semiconductor devices mounted thereon or the encapsulated wafer having semiconductor devices formed thereon into each individual semiconductor apparatus.

10. A method for manufacturing a semiconductor apparatus, comprising the steps of:
(1) coating a device-mounted surface of a substrate having semiconductor devices mounted thereon or a device-formed surface of a wafer having semiconductor devices formed thereon with the encapsulating resin layer of the base-attached encapsulant according to claim 4,
(2) collectively encapsulating the device-mounted surface or the device-formed surface by heating to cure the encapsulating resin layer, and
(3) dicing the encapsulated substrate having semiconductor devices mounted thereon or the encapsulated wafer having semiconductor devices formed thereon into each individual semiconductor apparatus.

11. A method for manufacturing a semiconductor apparatus, comprising the steps of:
(1) coating a device-mounted surface of a substrate having semiconductor devices mounted thereon or a device-formed surface of a wafer having semiconductor devices formed thereon with the encapsulating resin layer of the base-attached encapsulant according to claim 5,
(2) collectively encapsulating the device-mounted surface or the device-formed surface by heating to cure the encapsulating resin layer, and
(3) dicing the encapsulated substrate having semiconductor devices mounted thereon or the encapsulated wafer having semiconductor devices formed thereon into each individual semiconductor apparatus.

12. A method for manufacturing a semiconductor apparatus, comprising the steps of:
(1) coating a device-mounted surface of a substrate having semiconductor devices mounted thereon or a device-formed surface of a water having semiconductor devices formed thereon with the encapsulating resin layer of the base-attached encapsulant according to claim 6,
(2) collectively encapsulating the device-mounted surface or the device-formed surface by heating to cure the encapsulating resin layer, and
(3) dicing the encapsulated substrate having semiconductor devices mounted thereon or the encapsulated wafer having semiconductor devices formed thereon into each individual semiconductor apparatus.

13. A method for manufacturing a base-attached encapsulant for semiconductor encapsulation, comprising the steps of:
(i) producing bases by impregnating each fibrous base with a thermosetting resin composition containing a thermosetting resin, and heating to cure the thermosetting resin composition to produce each of the bases composed of a fibrous base layer in which the thermosetting resin composition is impregnated into the fibrous base and cured, a cured material layer A composed of a cured material of the thermosetting resin composition formed on one surface of the fibrous base layer, and a cured material layer B composed of a cured material of the thermosetting resin composition formed on the fibrous base layer at the opposite surface to the cured material layer A,
(ii) selecting a base in which the thickness Ta of the cured material layer A is 0.5 μm or more, and the ratio Ta/Tb of the thickness Ta of the cured material layer A and the thickness Tb of the cured material layer B is in a range of 0.1 to 10 from the produced bases, and
(iii) forming an encapsulating resin layer containing an uncured or semi-cured thermosetting resin on the selected base at the same side as the cured material layer B.

14. The method for manufacturing a base-attached encapsulant according to claim 13, wherein the step (ii) is a step of selecting a base in which the thickness Ta of the cured material layer A is 0.5 μm or more, and the ratio Ta/Tb of the thickness Ta of the cured material layer A and the thickness Tb of the cured material layer B is in a range of 0.5 to 2.

15. The method for manufacturing a base-attached encapsulant according to claim 13, wherein the thermosetting resin composition contains colorant.

16. The method for manufacturing a base-attached encapsulant according to claim 14, wherein the thermosetting resin composition contains colorant.

17. The method for manufacturing a base-attached encapsulant according to claim 15, wherein the thermosetting resin composition contains the colorant in an amount of 0.1 to 30 parts by mass based on 100 parts by mass of the thermosetting resin composition.

18. The method for manufacturing a base-attached encapsulant according no claim 16, wherein the thermosetting resin composition contains the colorant in an amount of 0.1 to 30 parts by mass based on 1300 parts by mass of the thermosetting resin composition.
